(19) United States
(12) Patent Application Publication
(10) Pub. No.: US 2026/0180305 A1
(43) Pub. Date: Jun. 25, 2026

(54) CURRENT DETECTION CIRCUIT AND OVER-CURRENT PROTECTION DEVICE

(71) Applicant: STMICROELECTRONICS INTERNATIONAL N.V., Geneva (CH)

(72) Inventor: Karl GRANGE, Tours (FR)

(21) Appl. No.: 19/411,851

(22) Filed: Dec. 8, 2025

(30) Foreign Application Priority Data
Dec. 20, 2024 (FR) 2414939

(51) Int. Cl. H02H 1/00; G01R 19/15; G01R 19/165; H02H 3/08

(52) U.S. Cl. CPC H02H 1/0007; G01R 19/15; G01R 19/16528; G01R 19/16571; H02H 3/08

(57) ABSTRACT

The present disclosure relates to a current sensing circuit comprising at least several pairs of first and second field-effect transistors. In an example current sensing circuit, the first and second field-effect transistor are configured such that: a first one of the source and drain electrodes of each of the first and second transistors is coupled to an input of the current sensing circuit on which a current to be sensed is intended to be applied; and for each pair of one of the first transistors and of one of the second transistors, the size ratio W₁/L₁ of the first transistor is higher than the size ratio W₂/L₂ of the second transistor, with W₁ and W₂ corresponding to the widths of the active areas of the first and second transistors, and L₁ and L₂ corresponding to the lengths of the active areas of the first and second transistors.

### CROSS REFERENCE TO RELATED APPLICATION(S)

This application claims the priority benefit of French Patent Application Number 24/14939, filed on Dec. 20, 2024, entitled “CIRCUIT DE DETECTION DE COURANT ET DISPOSITIF DE PROTECTION CONTRE LES SURINTENSITES”, which is hereby incorporated by reference to the maximum extent allowable by law.

### TECHNICAL FIELD

The present description relates generally to current sensing and overcurrent protecting fields, applied for example to protect connection interfaces.

### BACKGROUND

Some connection interfaces, such as USB (Universal Serial Bus) interfaces, specifically USB-C, or HDMI (High-Definition Multimedia Interface), or DP (Display Port), are protected against possible overcurrent through an OCP (Over-Current Protection) protection device.

Such a protection device is generally interposed between a load, for example formed by the computer comprising the connection interface equipped with the protection device, and a wire equipped with a plug connected to the connection interface. The other terminal of the wire is coupled to electronic elements and components that could be considered as a power supply source.

The protection device includes a switch allowing to stop the electric link between the power supply source and load in case of overcurrent over the electric link, for example due to an overload or a shorting. The protection device includes a current sensing circuit intended to generate, from a current flowing between the power supply source and load, an electric voltage proportional to this current. To this end, the current sensing circuit is configured to generate a fraction of a charging current Iₒᵤₜ sent to the load, i.e. generate a current Iₒᵤₜ/N, with N a real number higher than 1, and convert this current Iₒᵤₜ/N into a voltage. The current sensing circuit thus outputs a control signal sent to the input of a control circuit of the switch, and the value of which, depending on that of the obtained voltage, controls whether or not the electric link between the power supply source and load according to the value of the voltage is stopped.

The current sensing circuit includes a current sensing block configured to extract the current Iₒᵤₜ/N based on the current received from the power supply source, and send it into a particular branch of the block. The current sensing block also includes an element for converting the current Iₒᵤₜ/N into a voltage, this converting element corresponding to an electric resistance, for example.

The current sensing block includes a layout of the SenseFET (Sense Field-Effect Transistor) type comprising first and second MOSFET (Metal-Oxide-Semiconductor Field-Effect Transistor) transistors being matched but having different sizes. These sizes are so that the ratio W/L of the first transistor is equal to N, and that of the second transistor is equal to 1, with W and L respectively corresponding to the width and length of the active area of the considered transistor. These size ratios allow the charging current Iₒᵤₜ flowing through the first transistor and the current Iₒᵤₜ/N flowing through the second transistor. Except this difference in sizes, the first and second transistors are matched transistors, i.e. are performed in a same substrate, and include a same layout of the different semiconductor regions so that their electric behaviours are similar.

In such an architecture, the first and second transistors operate in reverse ohmic region. Thus, when the device is OFF, a maximum voltage of around 0.6 V, i.e. the threshold voltage of the transistor's drain-source diode, is developed across the first and second transistors. With such operation, the voltage class of the first and second transistors can be lower than the input voltage, which significantly improves matching between the first and second transistors, as the matching error is proportional to the voltage class of a MOSFET transistor. The current sensing block also includes a differential amplifier the inputs of which are coupled to the first and second transistors, and having an offset current I_{offset} that is added with the current fraction Iₒᵤₜ/N, and forming an error term within the measured current. The offset current is so that I_{offset}=V_{offset}/(N·RONₚ), with RONₚ corresponding to the ON resistance, or reverse ohmic resistance, of the first transistor, and V_{offset} the offset voltage of the amplifier. The offset current is thus proportional to the maximum current limit of the first transistor.

One solution to modulate the error term according to the current limit consists in modulating the gate-source voltage V_{GS} applied between the first and second transistors. Thus, when the maximum current is weakly limited, the error term could also be decreased to keep constant the matching or pairing between the transistors, and thus to keep constant a sensing accuracy while having a low voltage V_{GS}. However, In case of a high current, the error term is also high. adjusting the voltage V_{GS} yet requires analog elements being costly as concerns semiconductor surface, such as a digital-analog converter. In addition, decreasing voltage V_{GS} causes a decrease in the matching of the transistors, and thus a decrease in the accuracy of the performed current sensing.

### BRIEF SUMMARY

There is a need to provide a current sensing circuit as well as an overcurrent protection device having none of the drawbacks of the known circuits and devices.

One embodiment overcomes some or all drawbacks of the known solutions and provides a current sensing circuit comprising at least several pairs of first and second field-effect transistors, so that:
a first one of the source and drain electrodes of each of the first and second transistors is coupled to an input of the current sensing circuit on which a current to be sensed is intended to be applied;
for each pair of one of the first transistors and of one of the second transistors, the size ratio W₁/L₁ of the first transistor is higher than the size ratio W₂/L₂ of the second transistor, with W₁ and W₂ corresponding to the widths of the active areas of the first and second transistors, and L₁ and L₂ corresponding to the lengths of the active areas of the first and second transistors.

According to a particular embodiment, the current sensing circuit comprises a first output coupled to a second one of the source and drain electrodes of the first transistors, and on which a charging current Iₒᵤₜ is intended to be delivered, and a second output on which a voltage representative of a fraction of the charging current Iₒᵤₜ/N is intended to be delivered, with N=(W₁·L₂)/(L₁·W₂).

According to a particular embodiment, the current sensing circuit further includes a differential amplifier comprising a first input coupled to the second source or drain electrodes of the first transistors, and a second input coupled to the second source or drain electrodes of the second transistors.

According to a particular embodiment, the current sensing circuit further includes a third field-effect transistor, comprising a gate coupled to an output of the differential amplifier, a first source or drain electrode coupled to the second source or drain electrode of the second transistors, and a second source or drain electrode coupled to the second output of the current sensing circuit.

According to a particular embodiment, the current sensing circuit further includes an element for converting the fraction of the charging current Iₒᵤₜ/N into the voltage representative of the charging current fraction Iₒᵤₜ/N.

According to a particular embodiment, the converting element includes at least one electric resistor comprising a first electrode coupled to the second source or drain electrode of the third field-effect transistor, and a second electrode coupled to a reference electric potential.

According to a particular embodiment, the current sensing circuit comprises m pairs of first and second transistors, and further comprises a logic control circuit configured to receive an input digital value, and deliver, on m outputs, control voltages being together representative of the input digital value, each of the m outputs being coupled to the gates of one of the m pairs of first and second transistors, with m an integer higher than, or equal to, 2.

According to a particular embodiment, the logic control circuit is configured to convert the input digital value thermometrically encoded into m control voltages.

According to a particular embodiment, the logic control circuit includes at least one charge pump circuit configured so that the maximum value of each of the control voltages output is higher than the maximum value of each of the voltages corresponding to one of the bits of the input digital value.

According to a particular embodiment, the first and second transistors are of N-type.

It is also proposed an overcurrent protection device, comprising at least one current sensing circuit according to a particular embodiment.

According to a particular embodiment, the current sensing circuit includes the second output on which a voltage representative of a fraction of the charging current Iₒᵤₜ/N is intended to be delivered, and the protection device further includes a comparator comprising a first input coupled to the second output of the current sensing circuit, and a second input configured to receive a reference voltage.

According to a particular embodiment, the protection device further comprises a control circuit comprising an input coupled to an output of the comparator, and an output on which a protection-control signal is intended to be delivered.

According to a particular embodiment, the protection device further includes a switch configured to connect or not an input of the protection device to an output of the protection device, and comprises a control input coupled to a switching control circuit an input of which is coupled to the output of the control circuit, and an output of which is coupled to a control input of the switch.

It is also proposed a connection interface comprising at least one protection device according to a particular embodiment.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 illustrates an example current sensing circuit according to a specific embodiment;

FIG. 2 illustrates the value of the ON resistance formed by the first ON transistor(s), and the value of the error term obtained as a function of the number of pairs of first and second ON transistors in a current sensing circuit according to a specific embodiment;

FIG. 3 illustrates active areas of transistors of a current sensing circuit according to a specific embodiment;

FIG. 4 schematically illustrates a part of a logic control circuit used in a current sensing circuit according to a specific embodiment;

FIG. 5 schematically illustrates an example embodiment of a logic control circuit used in a current sensing circuit according to a specific embodiment;

FIG. 6 and FIG. 7 illustrate an example embodiment of a connection interface comprising an overcurrent protection device comprising in turn a current sensing circuit according to a specific embodiment.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail. In particular, different elements (transistors, differential amplifier, logic control circuit, charge pump circuit, switching control circuit, etc.) are not described in detail. Those skilled in the art will be able to perform in detail these elements based on the functional description of these elements hereinafter provided.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements. Further, the terms “coupled”, “linked”, and “connected” are here used to designate electrical coupling, or links, or connections.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures as orientated during normal use.

Unless specified otherwise, the expressions “around”, “approximately”, “substantially” and “in the order of” signify within 10%, and preferably within 5%.

Similarly, unless specified otherwise, the specified value ranges include the ends of these ranges.

An example embodiment of a current sensing circuit 100 is hereinafter described in relation to FIG. 1.

Circuit 100 includes several pairs, here m pairs of first and second transistors respectively referenced 102.1 to 102.m and 104.1 to 104.m, with m an integer higher than, or equal to, 2. The pairs of first and second transistors 102.1-102.m and 104.1-104.m are parallelly coupled to each other, i.e. the first transistors 102.1-102.m are parallelly coupled to each other, and the second transistors 104.1-104.m are parallelly coupled to each other.

For each pair of one of the first transistors 102.1-102.m, and of one 41 of second the transistors 104.1-104.m, the size ratio W₁/L₁ of the first transistor 102.i is higher than the size ratio W₂/L₂ of the second transistor 104.i, with W₁ and W₂ corresponding to the widths of the active areas of the first and second transistors 102.i, 104.i, and L₁ and L₂ corresponding to the lengths of the active areas of the first and second transistors 102.i, 104.i, with i an integer of between 1 and m. For example, the number m could be of between 2 and 1000, and for example equal around 100.

The value of W1 may be the same for all the first transistors.

The value of L1 may be the same for all the first transistors.

The value of W2 may be the same for all the second transistors.

The value of L2 may be the same for all the second transistors.

In addition to the specific size ratios hereinabove mentioned, for each of the pairs of first and second transistors 102.1-102.m and 104.1-104.m, the first transistor 102.i is matched with the second transistor 104.i. Thus, for each of the pairs of first and second transistors 102.1-102.m and 104.1-104.m, the first and second transistors 102.i, 104.i are performed in a same semiconductor portion, and include a similar layout however except as regards different sizes W et L.

In the described embodiment, the first and second transistors 102.1-102.m and 104.1-104.m are field-effect transistors, here N-type MOSFETs. However, it is possible that these transistors are P-type.

A first one of the source and drain electrodes of each of the first and second transistors 102.1-102.m and 104.1-104.m is coupled to an input 106 of the circuit 100 on which a current to be sensed is intended to be applied. In the described example embodiment, the first and second transistors 102.1-102.m and 104.1-104.m being N-type, and as these transistors are intended to operate in reverse ohmic region, the first one of the source and drain electrodes of these transistors corresponds to the source electrode.

In the described example embodiment, the circuit 100 includes a first output 108 coupled to a second one of the source and drain electrodes of the first transistors 102.1-102.m (drain electrode in the described example embodiment), and on which a charging current Iₒᵤₜ is intended to be delivered. In addition, the circuit 100 includes a second output 110 on which a voltage representative of a fraction of the charging current Iₒᵤₜ/N is intended to be delivered, with N=(W1·L2)/(L1·W2).

In the described example embodiment, the circuit 100 further includes a differential amplifier 112 comprising a first input, for example corresponding to its inverting input, coupled to the second source or drain electrodes of the first transistors 102.1-102.m and to the first output 108, and a second input (the non-inverting input in the described example) coupled to the second source or drain electrodes of the second transistors 104.1-104.m (drain electrode in the described example embodiment).

In the described example embodiment, the circuit 100 further includes a third field-effect transistor 114, such as a MOSFET for example of N-type, comprising a gate coupled to an output of the differential amplifier 112, a first source or drain electrode (drain electrode in the described example embodiment) coupled to the second source or drain electrodes of the second transistors 104.1-104.m, and a second source or drain electrode (source electrode in the described example embodiment) coupled to the second output 110 of the circuit 100.

In the described example embodiment, the circuit 100 further includes a circuit for converting the fraction of the charging current Iₒᵤₜ/N into a voltage representative of the fraction of the charging current Iₒᵤₜ/N. In the example shown in FIG. 1, the converting element includes at least one electric resistor 116 comprising a first electrode coupled to the second source or drain electrode of the third MOS transistor 114, and a second electrode coupled to a reference electric potential, for example, ground of circuit 100.

In the described example embodiment, the circuit further includes a logic control circuit 118 configured to receive an input digital value which, in this example, could have m different values. The logic control circuit 118 is configured to deliver on m outputs, m control voltages Φ1-Φm that together are representative of the input digital value, each of the m outputs being coupled to the gates of one of the m pairs of first and second transistors 102.1-102.m and 104.1-104.m. According to a specific embodiment, the logic control circuit 118 is configured to convert the input digital value thermometrically encoded into m control voltages Φ1-Φm.

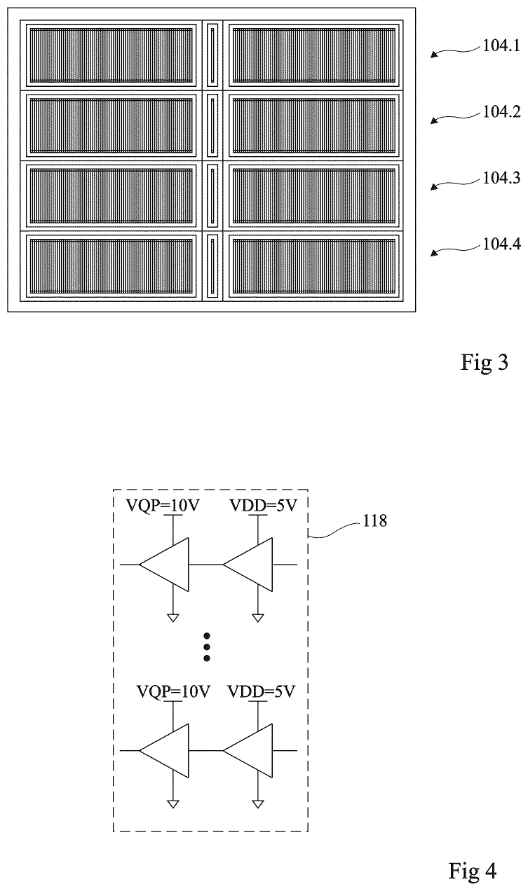

For example, the first transistors 102.1-102.m have the same electrical characteristics as each other, and the second transistors 104.1-104.m have the same electrical characteristics as each other. Thus, turning ON each pair of first and second transistors has the same effect, from the electrical point of view, within the circuit 100. FIG. 3 schematically illustrates same active areas of four second transistors 104.1-104.4 identical to each other.

In the circuit 100, a current is intended to be applied on the input 106. The different pairs of first and second transistors parallelly coupled to each other are digitally controlled via the circuit 118 so as that the value of the obtained error term is adjusted, and thus the accuracy in current sensing performed by circuit 100 is controlled. The number of pairs of first and second transistors which are ON, and thus the accuracy of the circuit, may be statistic parameters which are defined during the powering of the circuit. Indeed, unlike a current sensing circuit in which the value of the voltage Ves applied on two transistors, one delivering the charging current Iₒᵤₜ and the other one delivering the current fraction Iₒᵤₜ/N, is adjusted in order to modulate the ON resistance of the transistor delivering the charging current Tout, and thus the error term present within the branch in which the current fraction Iₒᵤₜ/N is sent, adjusting the obtained error term into the current fraction Iₒᵤₜ/N is here performed by turning ON a more or less high number of pairs of first and second transistors, the value of the voltage V_{GS} applied to the pairs of first and second transistors being unaltered.

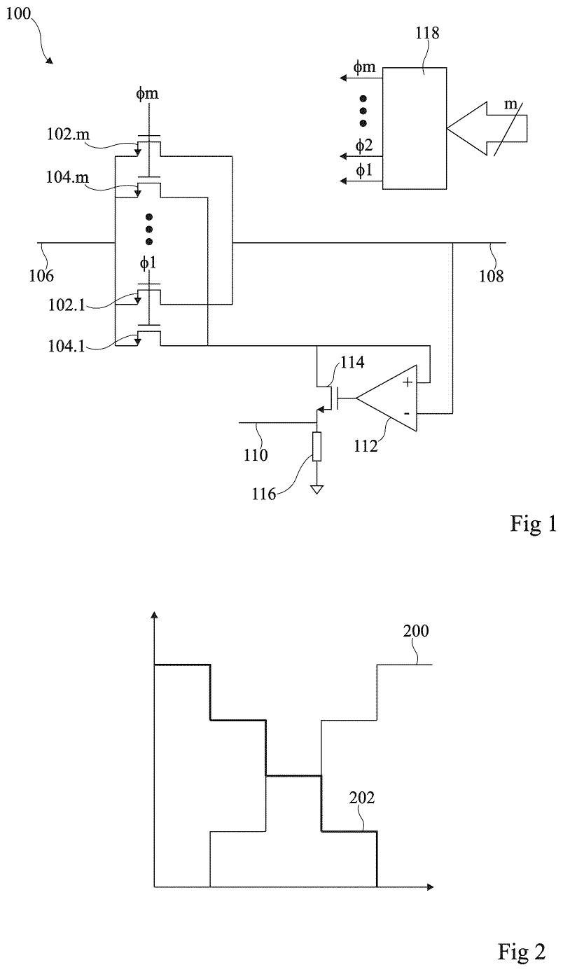

FIG. 2 illustrates the value of the ON resistance formed by the first transistor(s) 102.1-102.m being turned ON (curve 200), and the value of the error term obtained in the current fraction Iₒᵤₜ/N (curve 202) as a function of the number of pairs of first and second transistors being turned ON, and thus of the input digital value received by the logic control circuit 118. In this example, the curves 200 and 202 are each stairway-shaped, and so that each value modification of each of them corresponds to the turning ON of an additional pair of first and second transistors.

In such a circuit 100, matching between the first and second transistors 102.1-102.m and 104.1-104.m is thus not damaged due to adjusting the voltage V_{GS} applied to the first and second transistors 102.1-102.m and 104.1-104.m. Further, the value of the ON resistance RON obtained for the first transistors 102.1-102.m is matched according to the level for limiting the obtained current, by selecting the number of pairs of first and second transistors being ON.

The circuit 100 has also as an advantage not to require analog circuits for controlling transistors, such circuits requiring a high semiconductor surface.

FIG. 4 schematically illustrates a part of the components of an example embodiment of the logic control circuit 118. In this example, the logic components of the circuit 118 are configured to convert input digital signals, the voltage levels of which are for example in the order of 0 and 5 V, into output digital signals the voltage levels of which are higher than input ones, for example in the order of 0 and 10 V.

In the described example embodiment, the logic control circuit 118 includes at least one charge pump circuit 120 configured so that the maximum value of each of the control voltages output by circuit 118 is higher than the maximum value of each of the voltages corresponding to one of the bits of the input digital value.

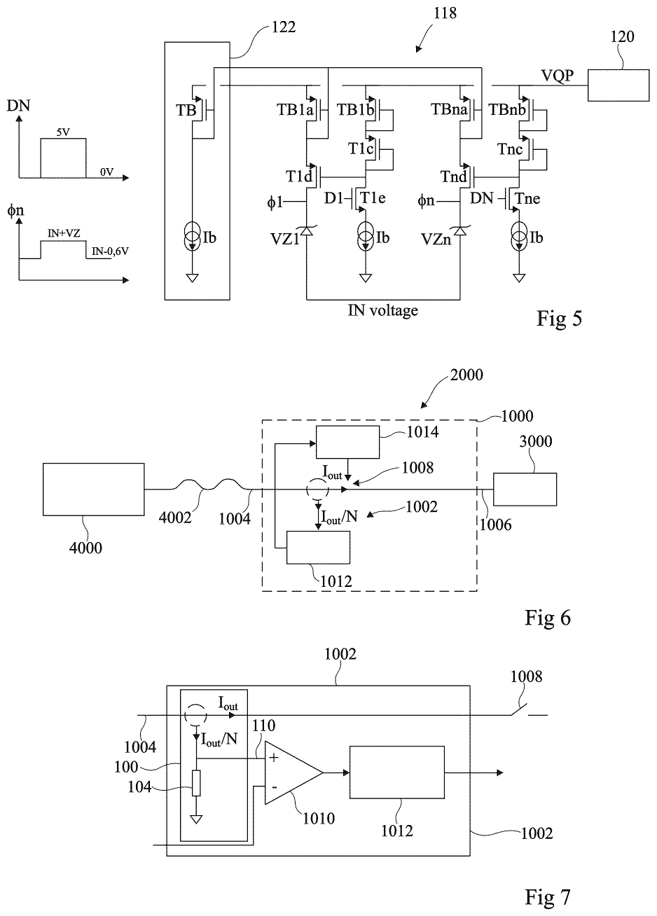

FIG. 5 schematically illustrates an example embodiment of the logic control circuit 118 comprising such a charge pump circuit 120. In this Figure, the bits of the input digital value are designated with references D1-DM, and each have voltage levels equal to 0 or 5 V, and the control voltages output by the circuit 118 are designated with references Φ1-Φm, and each have voltage levels equal to IN-0, 6 V (IN being the power supply voltage of the circuit 118) and IN+VZ, where VZ is the Zener voltage required to control the transistors, for example 5 V for MOSFET transistors with a maximum gate voltage of 5 V.

The control logic circuit 118 generates a voltage Φn=IN_voltage+VZn when the voltage DN is equal to a value corresponding to a ‘1’ state, and generates a voltage Φn=IN_voltage when the voltage DN is equal to a value corresponding to a ‘0’ state. VZn corresponds to the threshold voltage of Zener diodes Dz1 to DzN and is chosen to be equal to the maximum voltage V_{GS} admissible by transistors 102.x and 104.x of FIG. 1, with x between 1 and m.

For example, all the transistors in the control logic circuit 118 have the same dimensions. In the example shown in FIG. 5, the TBx transistors correspond to bias transistors whose voltage V_{GS} is set by the TB transistor of the bias branch 122. The TBx transistors are connected as a current source: the maximum current that can flow through these transistors is equal to the current flowing through transistor TB, i.e. the current Ib.

When the control signal DN is equal to a value corresponding to a ‘0’ state, all TBnx/Tnx transistors are OFF. In this case, no current flows through the Zener diode and Φn=IN_voltage.

When the control signal DN is equal to a value corresponding to a ‘1’ state:
transistor Tne switches ON. Transistors TBnb and Tnc are therefore also crossed by a current Ib.
the gate of transistor Ind develops a voltage equal to VQP-2. Ves, where V_{GS} is the gate-source voltage of a transistor through which current Ib flows. When all the transistors in circuit 118 have the same dimensions, the value of V_{GS} is similar for each of them when the same current flows through them.
the gate voltage across transistor Ind biases transistors Ind and TBna ON.
transistor TBna is biased as a current source, and therefore generates a current equal to Ib.
the Zener diode is biased at current Ib and voltage Φn=IN_voltage+VZn.
operation is obtained with VQP>IN_voltage+VZn+2.V_{GS}.

The current sensing circuit 100 is for example used within an overcurrent protection device 1000 for example in turn used within a connection interface 2000. An example of such a device 1000 and of such a connection interface 2000 is illustrated in FIGS. 6 and 7.

In this example, the connection interface 2000 is of USB-, or HDMI-, or DP-type, and allows connecting a load 3000, such as a computer, to an electronic circuit 4000 considered to be a power supply source. In the described example embodiment, connecting the electronic circuit 4000 to the connection interface 2000 is performed via a wire 4002 equipped with a plug (not shown in FIGS. 6 and 7) coupled to the connection interface 2000. The device 1000 includes an assembly including the circuit 100.

In the described example embodiment, device 1000 includes an input 1004 to which the wire 4002 is coupled, and an output 1006 to which the load 3000 is coupled. The device 1000 is configured to deliver the charging current Iₒᵤₜ on the output 1006.

The device 1000 further includes a switch 1008 configured to connect or not the input 1004 to the output 1006.

In the described example embodiment, the circuit 100 includes its second output 110 coupled to a first input, for example the non-inverting input, of a comparator 1010 also comprising a second input, for example an inverting input, configured to receive a reference voltage to which the voltage obtained by converting the current Iₒᵤₜ/N is compared. This reference voltage is chosen as being stable and accurate, and for example equal to 1,2 V and named “reference bandgap”.

In the described example embodiment, the device 1000 further includes a control circuit 1012 comprising an input coupled to an output of the comparator 1010, and an output on which a protection-control signal is intended to be delivered.

Further, in the described example embodiment, the switch 1008 comprises a control input coupled to an output of a switching control circuit 1014 an input of which is coupled to the output of the control circuit 1012. The switching control circuit 1014 is configured to control the switching on and off of the switch 1008 according to the value of the received protection control signal.

In such a device 1000, when the delivered voltage at the output 110 is higher than the reference voltage applied in input of the comparator 1010, it is considered that an overload is present at the connection interface. A control signal is then sent to the switch 1008, from the switching control circuit 1014 controlled in turn by control circuit 1012, in order to stop the link between the load 3000 and the circuit 4000.

The circuit 100 implements a current sensing function allowing a sensing accuracy to be kept constant whatever the value of the current limit between the input 106 and output 108 of the circuit 100.

In addition, the circuit 100 allows digitally controlling the value of the ON resistance that the first transistors 102.1-102.m have, without reducing the gate voltage V_{GS} applied on the first and second transistors 102.1-102.m, 104.1-104.m, and thus without reducing the matching between the transistors of the circuit 100.

The current sensing circuit 100 could be used for other applications, for example for a high-side current measurement of an electric circuit.

As an example, the circuit 100 and the device 1000 could be used within an electronic equipment such as a smart watch.

The current sensing circuit and the protection device could for example be used in industry field. In particular, the current sensing circuit and the protection device could for example be used in developing green energies, or infrastructure electrification, for example for charge terminals or in integrating solar energy. The current sensing circuit and the protection device could also be used in the fields of Internet of Things or smart home field.

For example, the current sensing circuit and the protection device are intended to be used in personal electronics.

For example, the current sensing circuit and the protection device are intended to be used in communications equipment, or in computers and peripherals.

Various embodiments and variants have been described. Those skilled in the art will understand that certain features of these embodiments can be combined and other variants will readily occur to those skilled in the art.

Finally, the practical implementation of the embodiments and variants described herein is within the capabilities of those skilled in the art based on the functional description provided hereinabove.

1. A current sensing circuit comprising at least several pairs of first field-effect transistors and second field-effect transistors, wherein the current sensing circuit is configured such that:
a first one of a source electrode and a drain electrode of each of the first field-effect transistors and the second field-effect transistors is coupled to an input of the current sensing circuit on which a current to be sensed is to be applied;
for each pair of one of the first field-effect transistors and of one of the second field-effect transistors, a size ratio W₁/L₁ of the first field-effect transistors is higher than a size ratio W₂/L₂ of the second field-effect transistors, with W₁ and W₂ corresponding to widths of active areas of the first field-effect transistors and the second field-effect transistors, and L₁ and L₂ corresponding to lengths of the active areas of the first field-effect transistors and the second field-effect transistors.

2. The current sensing circuit of claim 1, further comprising a first output coupled to a second one of the source electrode and the drain electrode of the first field-effect transistors, and on which a charging current Iₒᵤₜ is to be delivered, and a second output on which a voltage representative of a fraction of the charging current Iₒᵤₜ/N is to be delivered, wherein N=(W₁·L₂)/(L₁·W₂).

3. The current sensing circuit of claim 2, further comprising a differential amplifier comprising a first input coupled to second source electrodes or second drain electrodes of the first field-effect transistors, and a second input coupled to second source electrodes or second drain electrodes of the second field-effect transistors.

4. The current sensing circuit of claim 3, further comprising a third field-effect transistor, wherein the third field-effect transistor comprises a gate coupled to an output of the differential amplifier, a first source electrode or a first drain electrode coupled to a second source electrode or a second drain electrode of the second field-effect transistors, and a second source electrode or a second drain electrode coupled to the second output of the current sensing circuit.

5. The current sensing circuit of claim 4, further comprising an element for converting the fraction of the charging current Iₒᵤₜ/N into the voltage representative of a charging current fraction Iₒᵤₜ/N.

6. The current sensing circuit of claim 5, wherein the element for converting includes at least one resistor comprising a first electrode coupled to the second source electrode or the second drain electrode of the third field-effect transistor, and a second electrode coupled to a reference electric potential.

7. The current sensing circuit of claim 1, comprising m pairs of first and second transistors, and further comprising a logic control circuit configured to receive an input digital value, and deliver, on m outputs, m control voltages being together representative of the input digital value, each of the m outputs being coupled to one or more gates of one of the m pairs of first field-effect transistors and the second field-effect transistors, with m an integer higher than or equal to 2.

8. The current sensing circuit according to claim 7, wherein the logic control circuit is configured to convert the input digital value thermometrically encoded into m control voltages.

9. The current sensing circuit according to claim 7, wherein the logic control circuit includes at least one charge pump circuit configured so that a maximum value of each of the m control voltages output is higher than a maximum value of each voltage corresponding to a bit of the input digital value.

10. The current sensing circuit according to claim 1, wherein the first field-effect transistors and the second field-effect transistors are of N-type.

11. An overcurrent protection device comprising at least one current sensing circuit of claim 1.

12. The overcurrent protection device of claim 11, wherein the current sensing circuit includes a second output on which a voltage representative of a fraction of a charging current Iₒᵤₜ/N is to be delivered, and further including a comparator comprising a first input coupled to the second output of the current sensing circuit, and a second input configured to receive a reference voltage.

13. The overcurrent protection device of claim 12, further comprising a control circuit comprising an input coupled to an output of the comparator, and an output on which a protection-control signal is intended to be delivered.

14. The overcurrent protection device of claim 13, further including a switch configured to connect or not connect an input of the overcurrent protection device to an output of the overcurrent protection device, and comprising a control input coupled to a switching control circuit an input of which is coupled to the output of the control circuit, and an output of which is coupled to a control input of the switch.

15. A connection interface comprising at least one overcurrent protection device of claim 11.
